(19) United States
(12) Patent Application Publication
(10) Pub. No.: US 2012/0112360 A1
(43) Pub. Date: May 10, 2012

(54) SEMICONDUCTOR CHIP, STACKED SEMICONDUCTOR PACKAGE HAVING THE SAME, AND METHOD FOR MANUFACTURING STACKED SEMICONDUCTOR PACKAGE

(75) Inventor: Ho Young SON, Cheongju-si (KR)

(73) Assignee: HYNIX SEMICONDUCTOR INC., Icheon-si (KR)

(21) Appl. No.: 13/243,638

(22) Filed: Sep. 23, 2011

(30) Foreign Application Priority Data
Nov. 8, 2010 (KR) 10-2010-0110241

(51) Int. Cl. H01L 23/48; H01L 21/56; H01L 25/03; H01L 21/60

(52) U.S. Cl. 257/774; 438/109; 257/E25.002; 257/E23.011; 257/E21.506; 257/E21.502

(57) ABSTRACT

A semiconductor chip includes a semiconductor chip body including a peripheral region, a first region and a second region, and having a plurality of memory banks formed in each of the first region and the second region; a plurality of first through electrodes formed in the peripheral region; and a plurality of second through electrodes formed in the first and second regions along a direction parallel to a minor axis of the semiconductor chip body.

### CROSS-REFERENCE TO RELATED APPLICATIONS

The present application claims priority to Korean patent application number 10-2010-110241 filed on Nov. 8, 2010, which is incorporated herein by reference in its entirety.

### BACKGROUND OF THE INVENTION

The present invention relates generally to a semiconductor chip, a stacked semiconductor package having the same, and a method for manufacturing a stacked semiconductor package.

The packaging technology for a semiconductor integrated circuit has continuously been developed to meet the demand toward miniaturization and high capacity. Recently, various techniques for stacked semiconductor packages are being developed in order to provide satisfactory results in terms of miniaturization, high capacity and mounting efficiency.

The term “stack”, which is referred to in the semiconductor industry, means to vertically pile at least two semiconductor chips or packages. Through stacking semiconductor chips or packages, in the case of a memory device, it is possible to realize a product having a memory capacity greater than that obtainable through semiconductor integration processes, and mounting area utilization efficiency can be improved.

Among stacked semiconductor packages, a stacked semiconductor package using through-silicon vias (TSVs) has a structure in which through electrodes are formed in each semiconductor chip and the semiconductor chips are stacked such that the semiconductor chips are electrically connected with one another through the through electrodes. By using the through electrodes in the stacked semiconductor package, an operation speed of a semiconductor package may increase. Further, since electrical connections are formed via the through electrodes, the volume of the semiconductor package may decrease.

FIG. 1 is a plan view illustrating a known semiconductor chip having through electrodes, FIG. 2 is a cross-sectional view taken along the line I-I′ of FIG. 1, and FIG. 3 is a cross-sectional view taken along the line II-II′ of FIG. 1.

Referring to FIGS. 1 through 3, a semiconductor chip 10 includes a peripheral region PERI, a first region FR and a second region SR. Here, the peripheral region PERI is formed between the first region FR and the second region SR which are separated from each other. A plurality of through electrodes 20 for transmission of signals and power are formed in the peripheral region PERI of the semiconductor chip 10. A plurality of memory banks BANK1, BANK2, . . . , and BANK8 and a plurality of second through electrodes 30 for providing power are formed in the first and second regions FR and SR of the semiconductor chip 10. The second through electrodes 30 are formed along the edges of the semiconductor chip 10 which extend in directions parallel to a major axis FD of the semiconductor chip 10. Further, bonding pads 40 used in a chip test are formed in the peripheral region PERI. However, in the case of forming a semiconductor package using such a semiconductor chip 10, an open fail may occur.

FIG. 4 is a perspective view explaining an open fail, and FIG. 5 is a cross-sectional view taken along the line I-I′ of FIG. 4.

Referring to FIGS. 4 and 5, semiconductor chips 10 each having the above-described structure are stacked such that their first and second through electrodes 20 and 30 are connected, and an underfill member 50 is dispensed on the side surfaces of the stacked semiconductor chips 10 by using a dispenser D. As the underfill member 50 is dispensed on the side surfaces of the stacked semiconductor chips 10, the underfill member 50 flows through a narrow space between the stacked semiconductor chips 10 by a capillary phenomenon, by which the narrow space between the stacked semiconductor chips 10 is filled. However, if the flowing distance of the underfill member 50 by the capillary phenomenon is long, the underfill member 50 may not be properly filled between the semiconductor chips 10, and thus a defect may be caused. Therefore, according to a known art, the underfill member 50 is filled by moving the dispenser D on the side surfaces of the semiconductor chips 10 which extend parallel to the major axes FD of the semiconductor chips 10.

However, the underfill member 50 may flow from the side surfaces of the semiconductor chips 10 on which the underfill member 50 is dispensed, to the upper surfaces of the semiconductor chips 10, and cover the second through electrodes 30. Due to this fact, an open fail may occur when stacking other semiconductor chips subsequently. In order to reduce a probability of the occurrence of the open fail, the second through electrodes 30 may be formed to be sufficiently separated from the side surfaces of the semiconductor chips 10 on which the underfill member 50 is dispensed. However, in this case, a chip size may increase.

### BRIEF SUMMARY OF THE INVENTION

Embodiments of the present invention are directed to a semiconductor chip, a stacked semiconductor package having the same, and a method for manufacturing a stacked semiconductor package, which are appropriate to prevent an open fail.

In an embodiment of the present invention, a semiconductor chip includes: a semiconductor chip body possessing a rectangular hexahedral shape, divided into a peripheral region and first and second regions which are separated from each other with the peripheral region interposed therebetween, and having a plurality of memory banks formed in each of the first region and the second region; a plurality of first through electrodes formed in the peripheral region; and a plurality of second through electrodes formed in the first and second regions outside the memory banks and disposed in a direction parallel to a minor axis of the semiconductor chip body.

The second through electrodes may be disposed adjacent to edges of the semiconductor chip body outside the memory banks in the first and second regions. Alternatively, the second through electrodes may be disposed between the memory banks in the first and second regions.

The peripheral region may be defined to extend across the semiconductor chip body in a direction parallel to a major axis of the semiconductor chip body, and the first through electrodes may be disposed in the peripheral region along the direction parallel to the major axis of the semiconductor chip body.

The semiconductor chip may further include bonding pads formed in the peripheral region.

In an embodiment of the present invention, a stacked semiconductor package includes: a plurality of semiconductor chips each including a semiconductor chip body possessing a rectangular hexahedral shape, divided into a peripheral region and first and second regions which are separated from each other with the peripheral region interposed therebetween, and having a plurality of memory banks formed in each of the first region and the second region, a plurality of first through electrodes formed in the peripheral region, and a plurality of second through electrodes formed in the first and second regions outside the memory banks and disposed in a direction parallel to a minor axis of the semiconductor chip body, the plurality of semiconductor chips being vertically stacked such that the first through electrodes and the second through electrodes thereof are connected; and an underfill member filled between the stacked semiconductor chips.

The second through electrodes of each semiconductor chip may be disposed adjacent to edges of the semiconductor chip body outside the memory banks in the first and second regions. Alternatively, the second through electrodes of each semiconductor chip may be disposed between the memory banks in the first and second regions.

The peripheral region of each semiconductor chip may be defined to extend across the semiconductor chip body in a direction is parallel to a major axis of the semiconductor chip body, and the first through electrodes may be disposed in the peripheral region along the direction parallel to the major axis of the semiconductor chip body.

Each semiconductor chip may further include bonding pads which are formed in the peripheral region.

In an embodiment of the present invention, a method for manufacturing a stacked semiconductor package includes the steps of: preparing a plurality of semiconductor chips each including a semiconductor chip body possessing a rectangular hexahedral shape, divided into a peripheral region and first and second regions which are separated from each other with the peripheral region interposed therebetween, and having a plurality of memory banks formed in each of the first region and the second region, a plurality of first through electrodes formed in the peripheral region, and a plurality of second through electrodes formed in the first and second regions outside the memory banks and disposed in a direction parallel to a minor axis of the semiconductor chip body; vertically stacking the plurality of semiconductor chips such that the first and second through electrodes of the plurality of semiconductor chips are connected; and dispensing an underfill member on side surfaces of the stacked semiconductor chips which are parallel to a major axis of the semiconductor chip body, and forming the underfill member between the stacked semiconductor chips.

The step of forming the underfill member between the stacked semiconductor chips may include the steps of: dispensing the underfill member while moving a dispenser on the sides surfaces of the stacked semiconductor chips which are parallel to the major axis of the semiconductor chip body, and filling the underfill member between the stacked semiconductor chips; and hardening the underfill member.

### BRIEF DESCRIPTION OF THE DRAWINGS

FIG. 1 is a plan view illustrating a known semiconductor chip having through electrodes.

FIG. 2 is a cross-sectional view taken along the line I-I′ of FIG. 1.

FIG. 3 is a cross-sectional view taken along the line II-II′ of FIG. 1.

FIG. 4 is a perspective view explaining an open fail.

FIG. 5 is a cross-sectional view taken along the line I-I′ of FIG. 4.

FIG. 6 is a perspective view illustrating a semiconductor chip in accordance with an embodiment of the present invention.

FIG. 7 is a cross-sectional view taken along the line I-I′ of FIG. 6.

FIG. 8 is a cross-sectional view taken along the line II-II′ of FIG. 6.

FIG. 9 is a perspective view illustrating a semiconductor chip in accordance with an embodiment of the present invention.

FIG. 10 is a cross-sectional view taken along the line I-I′ of FIG. 9.

FIG. 11 is a cross-sectional view taken along the line II-II′ of FIG. 9.

FIG. 12 is a perspective view illustrating a stacked semiconductor package in accordance with an embodiment of the present invention.

FIG. 13 is a perspective view illustrating a stacked semiconductor package in accordance with an embodiment of the present invention.

FIGS. 14A and 14B are perspective views explaining a method for manufacturing a stacked semiconductor package in accordance with an embodiment of the present invention.

FIGS. 15A and 15B are cross-sectional views taken along the lines I-I′ of FIGS. 14A and 14B.

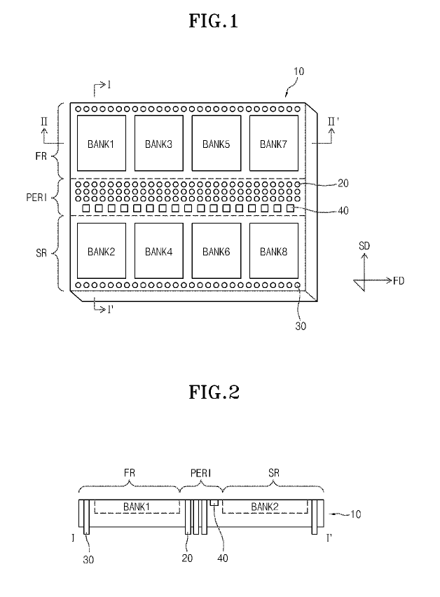

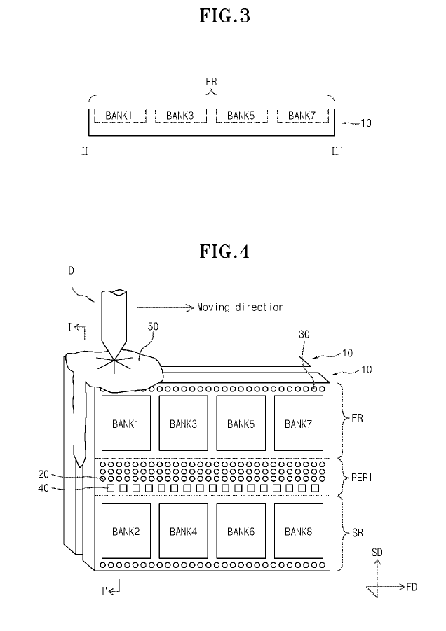

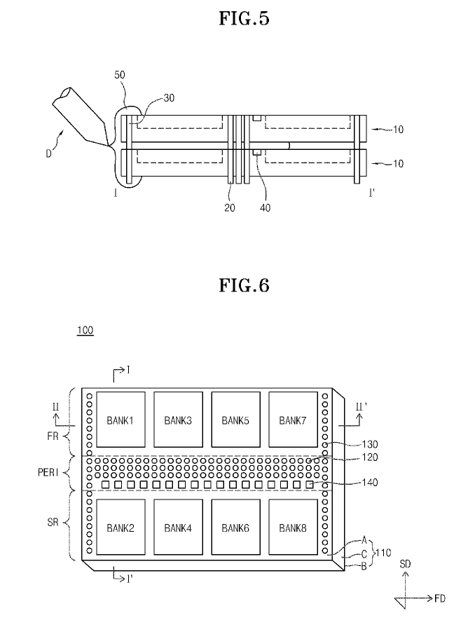

### DESCRIPTION OF SPECIFIC EMBODIMENTS

Hereafter, specific embodiments of the present invention will be described in detail with reference to the accompanying drawings.

It is to be understood herein that the drawings are not necessarily to scale and in some instances proportions may have been exaggerated in order to more clearly depict certain features of the invention.

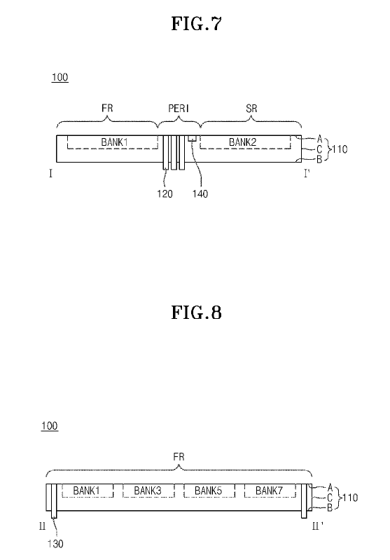

FIG. 6 is a perspective view illustrating a semiconductor chip in accordance with an embodiment of the present invention, FIG. 7 is a cross-sectional view taken along the line I-I′ of FIG. 6, and FIG. 8 is a cross-sectional view taken along the line II-II′ of FIG. 6.

Referring to FIGS. 6 through 8, the semiconductor chip 100 in accordance with an embodiment of the present invention includes a semiconductor chip body 110, first through electrodes 120, and second through electrodes 130. In addition, the semiconductor chip 100 may further include bonding pads 140.

The semiconductor chip body 110 has a rectangular hexahedral shape. The semiconductor chip body 110 with the rectangular hexahedral shape has a first surface A, a second surface B which faces away from the first surface A, and four side surfaces C which connect the first surface A and the second surface B with each other.

The semiconductor chip body 110 includes a first region FR, a second region SR and a peripheral region PERI. The peripheral region PERI extends across the semiconductor chip body 110 in the direction of a major axis FD of the semiconductor chip body 110. The first region FR and the second region SR are separated from each other and the peripheral region PERI is formed between the first region FR and the second region SR. A plurality of memory banks BANK1, BANK2, . . . , and BANK8 are formed in the first and second regions FR and SR. In an embodiment, the first, third, fifth and seventh memory banks BANK1, BANK3, BANK5 and BANK7 are formed in the first region FR, and the second, fourth, sixth and eighth memory banks BANK2, BANK4, BANK6 and BANK8 are formed in the second region SR.

The first through electrodes 120 are formed in the peripheral region PERI. In an embodiment, the first through electrodes 120 are formed in 3 rows along directions parallel to the major axis FD of the semiconductor chip body 110 in the peripheral region PERI. The first through electrodes 120 pass through the semiconductor chip body 110 including the first surface A and the second surface B. The second through electrodes 130 are formed adjacent to the edges of the semiconductor chip body 110 outside the memory banks BANK1, BANK2, . . . , and BANK8 in the first and second regions FR and SR along directions parallel to a minor axis SD of the semiconductor chip body 110. The second through electrodes 130 pass through the semiconductor chip body 110 including the first surface A and the second surface B.

The bonding pads 140, which may be used in the test of the semiconductor chip 100, are formed in a plural number on the first surface A of the semiconductor chip body 110. The plurality of bonding pads 140 are formed along the first through electrodes 120.

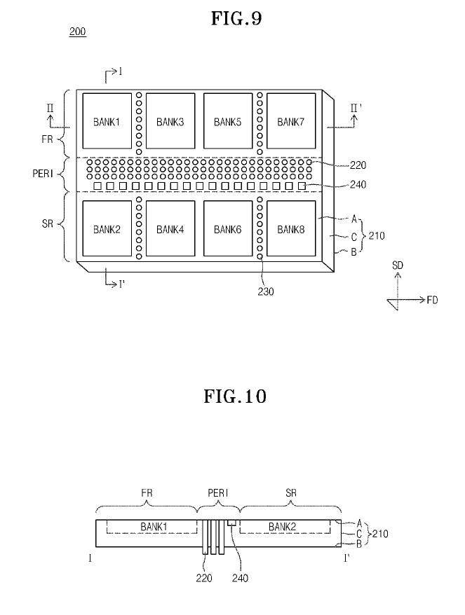

FIG. 9 is a perspective view illustrating a semiconductor chip in accordance with an embodiment of the present invention, FIG. 10 is a cross-sectional view taken along the line I-I′ of FIG. 9, and FIG. 11 is a cross-sectional view taken along the line II-II′ of FIG. 9.

The semiconductor chip in accordance with an embodiment of the present invention has substantially the same configuration as the semiconductor chip according to the embodiment described above with reference to FIGS. 6 through 8, except the positions of second through electrodes.

Referring to FIGS. 9 through 11, the semiconductor chip 200 in accordance with an embodiment of the present invention includes a semiconductor chip body 210, first through electrodes 220, and second through electrodes 230. In addition, the semiconductor chip 200 may further include bonding pads 240.

The semiconductor chip body 210 has a rectangular hexahedral shape. The semiconductor chip body 210 with the rectangular hexahedral shape has a first surface A, a second surface B which faces away from the first surface A, and four side surfaces C which connect the first surface A and the second surface B with each other. The semiconductor chip body 210 includes a first region FR, a second region SR and a peripheral region PERI. The peripheral region PERI extends across the semiconductor chip body 210 in the direction of a major axis FD of the semiconductor chip body 210. The first region FR and the second region SR are is separated from each other and the peripheral region PERI is formed between the first region FR and the second region SR.

A plurality of memory banks BANK1, BANK2, . . . , and BANK8 are formed in the first and second regions FR and SR. In an embodiment, the first, third, fifth and seventh memory banks BANK1, BANK3, BANK5 and BANK7 are formed in the first region FR, and the second, fourth, sixth and eighth memory banks BANK2, BANK4, BANK6 and BANK8 are formed in the second region SR.

The first through electrodes 220 are formed in the peripheral region PERI. In an embodiment, the first through electrodes 220 are formed in 3 rows along directions parallel to the major axis FD of the semiconductor chip body 210 in the peripheral region PERI. The first through electrodes 220 pass through the semiconductor chip body 210 including the first surface A and the second surface B. The second through electrodes 230 are formed between any adjacent banks out of the memory banks BANK1, BANK2, . . . , and BANK8 in the first and second regions FR and SR along directions parallel to a minor axis SD of the semiconductor chip body 210. In an embodiment, the second through electrodes 230 are formed between the first memory bank BANK1 and the third memory bank BANK3 and between the fifth memory bank BANK5 and the seventh memory bank BANK7 in the first region FR, and between the second memory bank BANK2 and the fourth memory bank BANK4 and between the sixth memory bank BANK6 and the eighth memory bank BANK8 in the second region SR, along the directions parallel to the minor axis SD of the semiconductor chip body 210. The second through electrodes 230 pass through the semiconductor chip body 210 including the first surface A and the second surface B.

The bonding pads 240, which may be used in the test of the semiconductor chip 200, are formed in a plural number on the first surface A of the semiconductor chip body 210. The plurality of bonding pads 240 are formed along the first through electrodes 220.

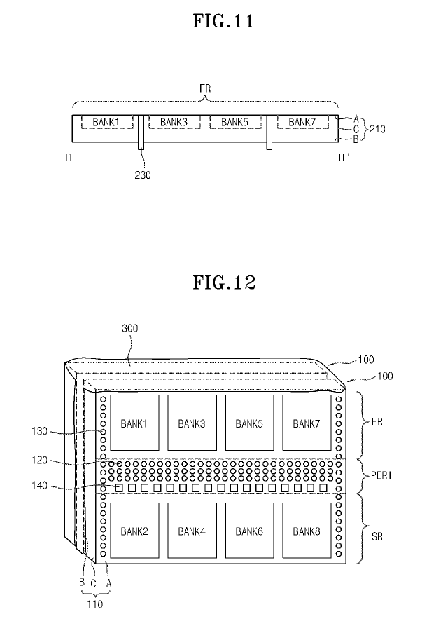

FIG. 12 is a perspective view illustrating a stacked semiconductor package in accordance with an embodiment of the present invention.

Referring to FIG. 12, the stacked semiconductor package in accordance with an embodiment of the present invention includes a plurality of semiconductor chips 100 and an underfill member 300.

Each semiconductor chip 100 may have substantially the same configuration as the semiconductor chip described above with reference to FIGS. 6 through 8. Therefore, repeated descriptions of the same component elements will be omitted herein, and the same terms and the same reference numerals will be used to refer to the same component parts.

The semiconductor chips 100 are vertically stacked such that first and second through electrodes 120 and 130 of the respective semiconductor chips 100 are coupled.

The underfill member 300 is filled between the stacked semiconductor chips 100. As the underfill member 300, a semiconductor encapsulant or a polymer resin for semiconductor bonding, containing a filler material for reinforcing a mechanical characteristic, may be used. Examples of the polymer resin for the underfill member 300 may include epoxy-based, polyimide-based, polyester-based and polyacrylate-based polymer resins. The filler material functions to prevent the mechanical characteristics of the underfill member 300 from deteriorating when bonding the semiconductor chips 100. As the filler material, silica (SiO2), silicon (Si), titanium dioxide (TiO2), polystyrene, polymetylmethacrylate, etc. may be used.

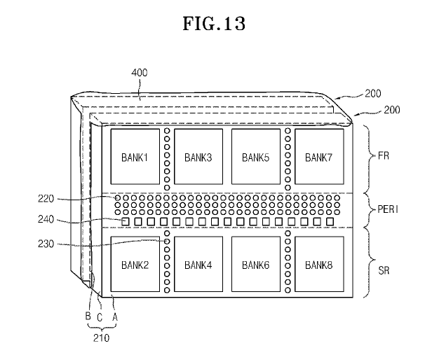

FIG. 13 is a perspective view illustrating a stacked semiconductor package in accordance with an embodiment of the present invention.

Referring to FIG. 13, the stacked semiconductor package in accordance with an embodiment of the present invention includes a plurality of semiconductor chips 200 and an underfill member 400.

Each semiconductor chip 200 may have substantially the same configuration as the semiconductor chip described above with reference to FIGS. 9 through 11. Therefore, repeated descriptions of the same component elements will be omitted herein, and the same terms and the same reference numerals will be used to refer to the same component parts.

The semiconductor chips 200 are vertically stacked such that first and second through electrodes 220 and 230 of the respective semiconductor chips 200 are coupled.

The underfill member 400 is filled between the stacked semiconductor chips 200. As the underfill member 400, a semiconductor encapsulant or a polymer resin for semiconductor bonding, containing a filler material for reinforcing a mechanical characteristic, may be used. Examples of the polymer resin for the underfill member 400 may include epoxy-based, polyimide-based, polyester-based and polyacrylate-based polymer resins. The filler material functions to prevent the mechanical characteristics of the underfill member 400 from deteriorating when bonding the semiconductor chips 200. As the filler material, silica (SiO2), silicon (Si), titanium dioxide (TiO2), polystyrene, polymetylmethacrylate, etc. may be used.

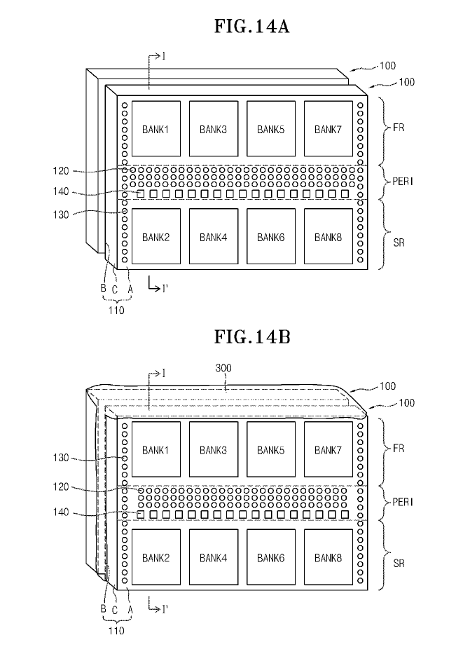

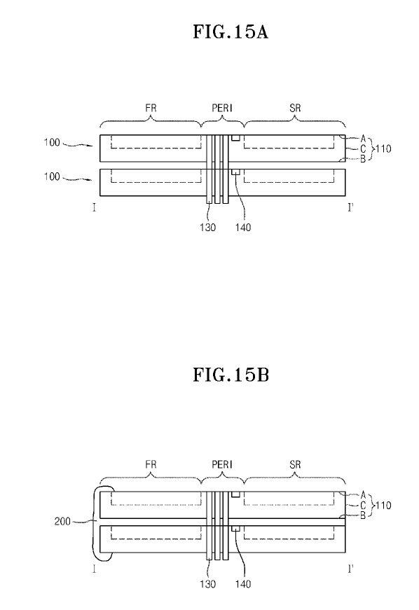

FIGS. 14A and 14B are perspective views explaining a method for manufacturing a stacked semiconductor package in accordance with an embodiment of the present invention, and FIGS. 15A and 15B are cross-sectional views taken along the lines I-I′ of FIGS. 14A and 14B.

Referring to FIGS. 14A and 15A, in order to manufacture a stacked semiconductor package according to an embodiment, a plurality of semiconductor chips 100 are prepared first.

Each semiconductor chip 100 includes a semiconductor chip body 110, first through electrodes 120, and second through electrodes 130. In addition, the semiconductor chip 100 may further include bonding pads 140.

The semiconductor chip body 110 has a rectangular hexahedral shape. The semiconductor chip body 110 with the rectangular hexahedral shape has a first surface A, a second surface B which faces away from the first surface A, and four side surfaces C which connect the first surface A and the second surface B with each other. The semiconductor chip body 110 includes a first region FR, a second region SR and a peripheral region PERI. The peripheral region PERI extends across the semiconductor chip body 110 in the direction of a major axis FD of the semiconductor chip body 110. The first region FR and the second region SR are separated from each other and the peripheral region PERI is formed between the first region FR and the second region SR. A plurality of memory banks BANK1, BANK2, . . . , and BANK8 are formed in the first and second regions FR and SR. In an embodiment, the first, third, fifth and seventh memory banks BANK1, BANK3, BANK5 and BANK7 are formed in the first region FR, and the second, fourth, sixth and eighth memory banks BANK2, BANK4, BANK6 and BANK8 are formed in the second region SR.

The first through electrodes 120 are formed in the peripheral region PERI. In an embodiment, the first through electrodes 120 are formed in 3 rows along directions parallel to the major axis FD of the semiconductor chip body 110 in the peripheral region PERI. The first through electrodes 120 pass through the semiconductor chip body 110 including the first surface A and the second surface B. The second through electrodes 130 are formed adjacent to the edges of the semiconductor chip body 110 outside the memory banks BANK1, BANK2, . . . , and BANK8 in the first and second regions FR and SR along directions parallel to a minor axis SD of the semiconductor chip body 110. The second through electrodes 130 pass through the semiconductor chip body 110 including the first surface A and the second surface B.

The bonding pads 140, which may be used in the test of the semiconductor chip 100, are formed in a plural number on the first surface A of the semiconductor chip body 110. The plurality of bonding pads 140 are formed along the first through electrodes 120.

Although it was described and illustrated in an embodiment that the second through electrodes 130 are formed adjacent to the edges of the semiconductor chip body 110 outside the memory banks BANK1, BANK2, BANK7 and BANK8 in the first and second regions FR and SR along the directions parallel to the minor axis SD of the semiconductor chip body 110, the present invention is not limited to such, and the second through electrodes 130 may be formed between any adjacent banks out of the memory banks BANK1, BANK2, BANK7 and BANK8 in the first and second regions FR and SR along directions parallel to the minor axis SD of the semiconductor chip body 110. For example, the second through electrodes 130 may be formed between the first memory bank BANK1 and the third memory bank BANK3 and between the fifth memory bank BANK5 and the seventh memory bank BANK7 in the first region FR, and between the second memory bank BANK2 and the fourth memory bank BANK4 and between the sixth memory bank BANK6 and the eighth memory bank BANK8 in the second region SR, along the directions parallel to the minor axis SD of the semiconductor chip body 110.

Then, the semiconductor chips 100 are vertically stacked and electrically connected by the first and second through electrodes 120 and 130.

Referring to FIGS. 14B and 15B, an underfill member 200 is dispensed on the side surfaces of the semiconductor chips 100 which extend parallel to the major axes FD of the semiconductor chips 100, while moving a dispenser D. As the underfill member 200 is dispensed, the underfill member 200 flows through a narrow space between the stacked semiconductor chips 100 by a capillary phenomenon, by which the narrow space between the stacked semiconductor chips 100 is filled with the underfill member 200.

The reason why the underfill member 200 is dispensed while moving the dispenser D along the major axes FD of the semiconductor chips 110 is to decrease the flowing distance of the underfill member 200 by the capillary phenomenon and reduce a probability of an occurrence of a defect due to insufficient filling of the underfill member 200.

As the underfill member 200, a semiconductor encapsulant or a polymer resin for semiconductor bonding, containing a filler material for reinforcing a mechanical characteristic, may be used. Examples of the polymer resin for the underfill member 200 may include epoxy-based, polyimide-based, polyester-based and polyacrylate-based polymer resins. The filler material functions to prevent the mechanical characteristics of the underfill member 200 from deteriorating when bonding the semiconductor chips 100. As the filler material, silica (SiO2), silicon (Si), titanium dioxide (TiO2), polystyrene, polymetylmethacrylate, etc. may be used.

Next, the underfill member 200 is hardened through a curing process.

As is apparent from the above description, in the present invention, since through electrodes are not formed at an edge where an underfill member is dispensed, a probability of an occurrence of an open fail may decrease even though the underfill member overflows to the upper surface of a semiconductor chip when dispensing the underfill member.

Although specific embodiments of the present invention have been described for illustrative purposes, those skilled in the art will appreciate that various modifications, additions and substitutions are possible, without departing from the scope and the is spirit of the invention as disclosed in the accompanying claims.

What is claimed is:

1. A semiconductor chip comprising:
a semiconductor chip body including a peripheral region, a first region and a second region, and having a plurality of memory banks formed in each of the first region and the second region;
a plurality of first through electrodes formed in the peripheral region; and
a plurality of second through electrodes formed in the first and second regions along a direction parallel to a minor axis of the semiconductor chip body.

2. The semiconductor chip according to claim 1, wherein the second through electrodes are formed adjacent to edges of the semiconductor chip body outside the memory banks in the first and second regions.

3. The semiconductor chip according to claim 1, wherein the second through electrodes are formed between the memory banks in the first and second regions.

4. The semiconductor chip according to claim 1, wherein the peripheral region is formed to extend in a direction parallel to a major axis of the semiconductor chip body.

5. The semiconductor chip according to claim 1, wherein the peripheral region is formed to extend in a direction parallel to a major axis of the semiconductor chip body, and the first through electrodes are formed in the peripheral region along the direction parallel to the major axis of the semiconductor chip body.

6. The semiconductor chip according to claim 1, further comprising:
bonding pads formed in the peripheral region.

7. A stacked semiconductor package comprising:
a plurality of semiconductor chips including a peripheral region, a first region and a second region, and having a plurality of memory banks formed in each of the first region and the second region, a plurality of first through electrodes formed in the peripheral region, and a plurality of second through electrodes formed in the first and second regions along a direction parallel to a minor axis of the semiconductor chip body, wherein the plurality of semiconductor chips are vertically stacked and electrically connected by the first through electrodes and the second through is electrodes thereof; and
an underfill member filled between the stacked semiconductor chips.

8. The stacked semiconductor chip according to claim 7, wherein the second through electrodes of each semiconductor chip are formed adjacent to edges of the semiconductor chip body outside the memory banks in the first and second regions.

9. The stacked semiconductor chip according to claim 7, wherein the second through electrodes of each semiconductor chip are formed between the memory banks in the first and second regions.

10. The stacked semiconductor chip according to claim 7, wherein the peripheral region of each semiconductor chip is formed to extend in a direction parallel to a major axis of the semiconductor chip body.

11. The stacked semiconductor chip according to claim 7, wherein the peripheral region of each semiconductor chip is formed to extend in a direction parallel to a major axis of the semiconductor chip body, and the first through electrodes are formed in the peripheral region along the direction parallel to the major axis of the semiconductor chip body.

12. The stacked semiconductor chip according to claim 7, wherein each semiconductor chip further includes bonding pads which are formed in the peripheral region.

13. A method for manufacturing a stacked semiconductor package, comprising the steps of:
preparing a plurality of semiconductor chips including a peripheral region, a first region and a second region, and having a plurality of memory banks formed in each of the first region and the second region, a plurality of first through electrodes formed in the peripheral region, and a plurality of second through electrodes formed in the first and second regions along a direction parallel to a minor axis of the semiconductor chip body;
vertically stacking and electrically connecting the plurality of semiconductor chips; and
dispensing an underfill member on side surfaces of the stacked semiconductor chips which are parallel to a major axis of the semiconductor chip body, and forming the underfill member between the stacked semiconductor chips.

14. The method according to claim 13, wherein the step of forming the underfill member between the stacked semiconductor chips comprises the steps of:
dispensing the underfill member while moving a dispenser on the sides surfaces of the stacked semiconductor chips which are parallel to the major axis of the semiconductor chip body, and filling the underfill member between the stacked semiconductor chips; and
hardening the underfill member.
